(19) United States
(12) Patent Application Publication
(10) Pub. No.: US 2026/0020142 A1
(43) Pub. Date: Jan. 15, 2026

(54) ORTHOGONAL DIFFERENTIAL VIAS DESIGN ON A PRINTED CIRCUIT BOARD

(71) Applicant: DELL PRODUCTS L.P., Round Rock, TX (US)

(72) Inventors: Sandor Farkas, Round Rock, TX (US); Bhyrav Mutnury, Round Rock, TX (US)

(21) Appl. No.: 18/773,127

(22) Filed: Jul. 15, 2024

(51) Int. Cl. H05K 1/02; H05K 1/11; H05K 3/42

(52) U.S. Cl. CPC H05K 1/0228; H05K 1/0222; H05K 1/115; H05K 3/42; H05K 2201/0707; H05K 2201/09227

(57) ABSTRACT

An information handling system includes a printed circuit board having first and second differential pairs fabricated on the printed circuit board. The first differential pair includes first and second vias. The first via is connected to a first signal trace on the printed circuit board. The second via is connected to a second trace on the printed circuit board. The second differential pair includes third and fourth vias and a shield. The third via is connected to a third signal trace on the printed circuit board. The fourth via is connected to a fourth trace on the printed circuit board. The third and fourth vias have an orthogonal via pattern. The shield is located between the first via and the second and third vias.

### FIELD OF THE DISCLOSURE

The present disclosure generally relates to information handling systems, and more particularly relates to orthogonal differential vias design on a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a printed circuit board having first and second differential pairs fabricated on the printed circuit board. The first differential pair includes first and second vias. The first via may be connected to a first signal trace on the printed circuit board. The second via may be connected to a second trace on the printed circuit board. The second differential pair includes third and fourth vias and a shield. The third via may be connected to a third signal trace on the printed circuit board. The fourth via may be connected to a fourth trace on the printed circuit board. The third and fourth vias have an orthogonal via pattern. The shield may be located between the first via and the second and third vias.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a top view of a portion of an embodiment of a printed circuit board with orthogonal differential pairs according to at least one embodiment of the present disclosure;

FIG. 2 is a diagram of a perspective view of a portion of an embodiment of a printed circuit board with orthogonal differential pairs according to at least one embodiment of the present disclosure;

FIG. 3 is a diagram of a top view of a portion of another embodiment of a printed circuit board with orthogonal differential pairs according to at least one embodiment of the present disclosure;

FIG. 4 is a diagram of a perspective view of a portion of another embodiment of a printed circuit board with orthogonal differential pairs according to at least one embodiment of the present disclosure;

FIG. 5 is a diagram of a top view of a portion of another embodiment of a printed circuit board with orthogonal differential pairs according to at least one embodiment of the present disclosure;

FIG. 6 is a diagram of a perspective view of a portion of another embodiment of a printed circuit board with orthogonal differential pairs according to at least one embodiment of the present disclosure;

FIG. 7 is a flow diagram of a method for creating orthogonal vias within a printed circuit board according to at least one embodiment of the present disclosure; and

FIG. 8 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

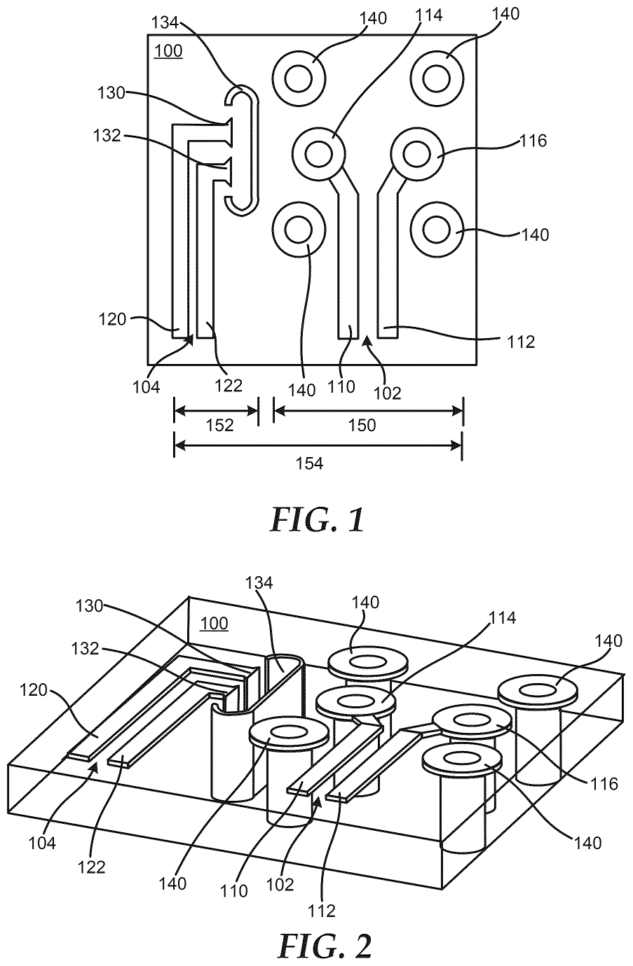

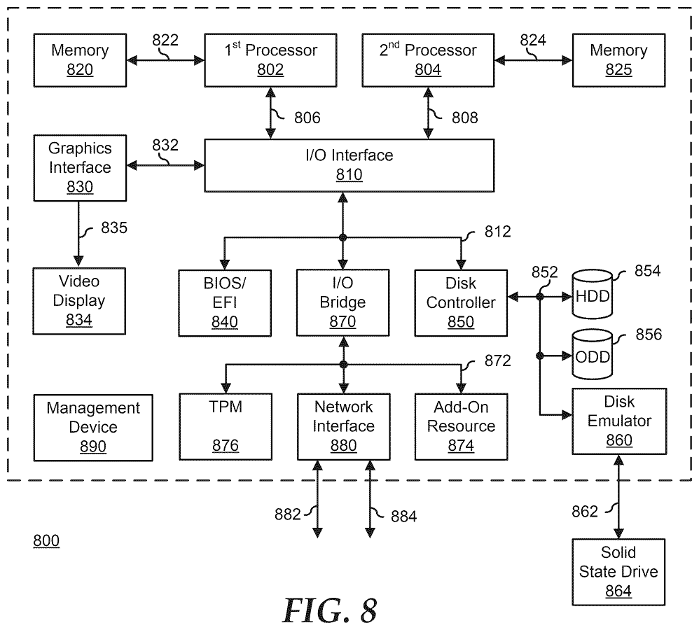

FIGS. 1 and 2 illustrate a printed circuit board (PCB) 100 of an information handling system, such as information handling system 800 of FIG. 8, according to an embodiment. For purpose of this disclosure information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a laptop computer, a smart phone, a tablet device or other consumer electronic device, a network server, a network storage device, a switch, a router, or another network communication device, or any other suitable device and may vary in size, shape, performance, functionality, and price.

PCB 100 includes differential pairs 102 and 104. Different pair 102 is formed from signal traces 110 and 112. In an example, signal trace 110 is connected to signal via 114 in PCB 100 and signal trace 112 is connected to signal via 116 in the PCB. Different pair 104 is formed from signal traces 120 and 122. PCB 100 also includes vias 130 and 132, a shield 134 and multiple ground vias 140. While vias 114, 116, 130, 132, and 140 and shield 134 are illustrated in FIG. 2 as extending from one surface of PCB 100 to the opposite surface of the PCB, these vias may extend in suitable distance within the PCB without varying from the scope of this disclosure. PCB 100 may include additional components without varying from the scope of this disclosure.

In an example, vias 114, 116 and 140 may be plated with any suitable conductive material including, but not limited to, copper, silver, gold, zinc, and nickel. The details of PCB manufacture, and particularly the forming of vias in a PCB are known in the art and will not be further described herein, except as needed to illustrate the current embodiments. After via 114 has been plated, signal trace 110 of differential pair 102 is routed on PCB 100, such that signal trace 110 physically and electrically connected to via 114. In this situation, via 114 may connect signal trace 110 to one or more signal layers within PCB 100. In an example, after via 116 has been plated, signal trace 112 of differential pair 102 is routed on PCB 100, such that signal trace 112 physically and electrically connected to via 116. Thus, via 116 may connect signal trace 112 to one or more signal layers within PCB 100. In an example, ground vias 140 may be referred to as stitching vias for different pair 102. In this example, ground vias 140 may provide differential pair 102 with isolation from an adjacent differential pair, such as differential pair 104.

In previous PCBs, the different pairs layouts would consist only of configurations similar to differential pair 102 having signal traces 110 and 112 and vias 114, 116, and 140. In these different pair configurations, an average width of the different pairs would be around sixty-six mils. One of ordinary skill in the art would recognize that mil is a unit of measurement utilized in routing on PCBs, and one mil equals one-thousandth of an inch or two hundred fifty-four ten-thousandths of a millimeter. In previous PCBs, this differential pair layout may be a density limiting factor and longer microstrip trace lengths, which is a hindrance at higher transmission speeds.

PCB 100 may be improved by the orthogonal via pattern of vias 130 and 132 of differential pair 104. Additionally, the orthogonal via pattern may increase routing density of multiple differential pairs on PCB 100 as compared to previous routing configurations for differential pairs. Also, the orthogonal via pattern may reduce crosstalk between differential pairs 102 and 104 as compared to previous routing configurations for differential pairs.

In certain examples, vias 130 and 132 may be orthogonal vias, such that the routing to and from the vias is at right angles. Vias 130 and 132 and shield 134 may be referred to as a shielded vertical conductive structure (VeCS) slot. In an example, vias 130 and 132 and shield 134 may be plated with any suitable conductive material including, but not limited to, copper, silver, gold, zinc, and nickel. The details of forming VeCS vias in a PCB are known in the art and will not be further described herein, except as needed to illustrate the current embodiments.

After via 130 has been plated, signal trace 120 of differential pair 104 is routed on PCB 100, such that signal trace 120 is physically and electrically connected to via 130. In this situation, via 130 may connect signal trace 120 to one or more signal layers within PCB 100. In an example, after via 132 has been plated, signal trace 122 of differential pair 104 is routed on PCB 100, such that signal trace 122 is physically and electrically connected to via 132. In this example, via 132 may connect signal trace 122 to one or more signal layers within PCB 100.

In certain examples, the orthogonal via pattern of vias 130 and 132 may reduce crosstalk between different pairs 102 and 104 as compared to adjacent different pairs without an orthogonal via pattern. For example, crosstalk from vias 130 and 132 may be symmetrical with respect to via 114, which in turn may create a low common mode noise on via 114 from vias 130 and 132. For example, the noise from vias 130 and 132 may have equal amplitude but opposite polarity such that the common mode noise is rejected or cancelled on via 114. In certain examples, traces 120 and 122 and vias 130 and 132 may have slight asymmetries due to manufacturing tolerances, skews, or the like. Based on these asymmetries, the noise cancellation may not be perfect between differential pairs 102 and 104. In an example, VeCS shield 134 located between vias 130 and 132 and 114 may block any common mode noise that is not cancelled based on the asymmetries. As described above, the orthogonal via pattern of vias 130 and 132 may reduce cross talk between differential pairs 102 and 104 and improve common mode noise rejection between the differential pairs.

As illustrated in FIG. 1, different pair layouts in PCB 100 may have different widths. For example, the layout of differential pair 102 includes grounding traces 110 and 102 and vias 114, 116, and 140 may have a width 150. In an example, width 150 may be approximately sixty-six mils. The layout of differential pair 104 includes traces 120 and 122, vias 130 and 132, and shield 134 may have a width 152. Width 152 may be approximately thirty-two mils. In certain examples, width 150 of the layout of differential pair 102 and width 152 of the layout of differential pair 104 may combine to form an overall width 154 of layouts of differential pairs 102 and 104. In an example, width 154 may be ninety-eight mils. In this situation, the average width of the layouts of differential pairs 102 and 104 may be forty-nine mils. This average width of the layouts may improve routing density in PCB 100 as compared to previous PCBs with multiple differential pairs that only have a layout similar to the layout of differential pair 102. One of ordinary skill in the art would recognize that widths 150, 152, and 154 may be any suitable amounts without varying from the scope of this disclosure. In an example, widths 150 and 152 of corresponding differential pairs 102 and 104 enable a reduction of overall space and microstrip breakout trace lengths in PCB 100, which in turn may improve signal integrity for different pairs 102 and 104 of PCB 100.

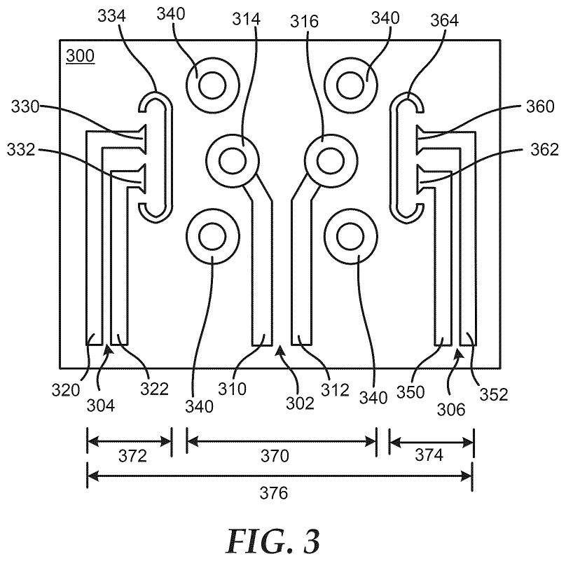

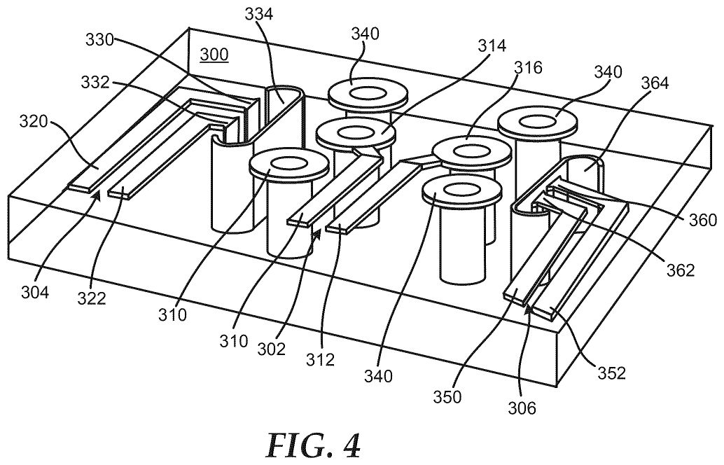

FIGS. 3 and 4 illustrate a portion of a PCB 300 of an information handling system, such as information handling system 800 of FIG. 8, according to at least one embodiment of the present disclosure. PCB 300 includes differential pairs 302, 304, and 306. Different pair 302 is formed from signal traces 310 and 312. In an example, signal trace 310 is connected to signal via 314 in PCB 300 and signal trace 312 is connected to signal via 316 in the PCB. Different pair 304 is formed from signal traces 320 and 322. PCB 300 also includes vias 330 and 332, a shield 334 and multiple ground vias 340. Differential pair 306 is formed from signal traces 350 and 352. PCB 300 also includes vias 360 and 362 and a shield 364. While vias 314, 316, 330, 332, 340, 360, and 362, and shields 334 and 364 are illustrated in FIG. 4 as extending from one surface of PCB 300 to the opposite surface of the PCB, these vias may extend in suitable distance within the PCB without varying from the scope of this disclosure. PCB 300 may include additional components without varying from the scope of this disclosure.

In an example, vias 314, 316 and 340 may be plated with any suitable conductive material including, but not limited to, copper, silver, gold, zinc, and nickel. The details of PCB manufacture, and particularly the forming of vias in a PCB are known in the art and will not be further described herein, except as needed to illustrate the current embodiments. After via 314 has been plated, signal trace 310 of differential pair 302 is routed on PCB 300, such that signal trace 310 physically and electrically connected to via 314. In this situation, via 314 may connect signal trace 310 to one or more signal layers within PCB 300. In an example, after via 316 has been plated, signal trace 312 of differential pair 302 is routed on PCB 300, such that signal trace 312 physically and electrically connected to via 316. Thus, via 316 may connect signal trace 312 to one or more signal layers within PCB 300. In an example, ground vias 340 may be referred to as stitching vias for different pair 302. In this example, ground vias 340 may provide differential pair 302 with isolation from adjacent differential pairs, such as differential pairs 304 and 306.

In certain examples, vias 330 and 332 may be orthogonal vias, such that the routing to and from the vias is at right angles. Vias 330 and 332 and shield 334 may be referred to as a VeCS slot. In an example, vias 330 and 332 and shield 334 may be plated with any suitable conductive material including, but not limited to, copper, silver, gold, zinc, and nickel. The details of forming VeCS vias in a PCB are known in the art and will not be further described herein, except as needed to illustrate the current embodiments.

After via 330 has been plated, signal trace 320 of differential pair 304 is routed on PCB 300, such that signal trace 320 is physically and electrically connected to via 330. In this situation, via 330 may connect signal trace 320 to one or more signal layers within PCB 300. In an example, after via 332 has been plated, signal trace 322 of differential pair 304 is routed on PCB 300, such that signal trace 322 is physically and electrically connected to via 332. In this example, via 332 may connect signal trace 322 to one or more signal layers within PCB 300.

In certain examples, the orthogonal via pattern of vias 330 and 332 may reduce crosstalk between different pairs 302 and 304 as compared to adjacent different pairs without an orthogonal via pattern. For example, crosstalk from vias 330 and 332 may be symmetrical with respect to via 314, which in turn may create a low common mode noise on via 314 from vias 330 and 332. For example, the noise from vias 330 and 332 may have equal amplitude but opposite polarity such that the common mode noise is rejected or cancelled on via 314. In certain examples, traces 320 and 322 and vias 330 and 332 may have slight asymmetries due to manufacturing tolerances, skews, or the like. Based on these asymmetries, the noise cancellation may not be perfect between differential pairs 302 and 304. In an example, VeCS shield 334 located between vias 330 and 332 and 314 may block any common mode noise that is not cancelled based on the asymmetries. As described above, the orthogonal via pattern of vias 330 and 332 may reduce cross talk between differential pairs 302 and 304 and improve common mode noise rejection between the differential pairs.

In an example, vias 360 and 362 may be orthogonal vias, such that the routing to and from the vias is at right angles. Vias 360 and 362 and shield 364 may be referred to as a VeCS slot. In an example, vias 360 and 362 and shield 364 may be plated with any suitable conductive material including, but not limited to, copper, silver, gold, zinc, and nickel. The details of forming VeCS vias in a PCB are known in the art and will not be further described herein, except as needed to illustrate the current embodiments.

After via 360 has been plated, signal trace 350 of differential pair 306 is routed on PCB 300, such that signal trace 350 is physically and electrically connected to via 360. In this situation, via 360 may connect signal trace 350 to one or more signal layers within PCB 300. In an example, after via 362 has been plated, signal trace 352 of differential pair 306 is routed on PCB 300, such that signal trace 352 is physically and electrically connected to via 362. In this example, via 362 may connect signal trace 352 to one or more signal layers within PCB 300.

In an example, the orthogonal via pattern of vias 360 and 362 may reduce crosstalk between different pairs 302 and 306 as compared to adjacent different pairs without an orthogonal via pattern. For example, crosstalk from vias 360 and 362 may be symmetrical with respect to via 316, which in turn may create a low common mode noise on via 316 from vias 360 and 362. For example, the noise from vias 360 and 362 may have equal amplitude but opposite polarity such that the common mode noise is rejected or cancelled on via 316. In certain examples, traces 350 and 352 and vias 360 and 362 may have slight asymmetries due to manufacturing tolerances, skews, or the like. Based on these asymmetries, the noise cancellation may not be perfect between differential pairs 302 and 306. In an example, VeCS shield 364 located between vias 360 and 362 and 316 may block any common mode noise that is not cancelled based on the asymmetries. As described above, the orthogonal via pattern of vias 360 and 362 may reduce cross talk between differential pairs 302 and 306 and improve common mode noise rejection between the differential pairs.

As illustrated in FIG. 3, different pair layouts in PCB 300 may have different widths. For example, the layout of differential pair 302 includes grounding traces 310 and 302 and vias 314, 316, and 340 may have a width 370. In an example, width 370 may be approximately sixty-six mils. The layout of differential pair 304 includes traces 320 and 322, vias 330 and 332, and shield 334 may have a width 372. Width 372 may be approximately thirty-two mils. The layout of differential pair 306 includes traces 350 and 352, vias 360 and 362, and shield 364 may have a width 374. Width 374 may be approximately thirty-two mils. In certain examples, width 370 of the layout of differential pair 302, width 372 of the layout of differential pair 304, and width 374 of the layout of differential pair 306 may combine to form an overall width 376 of layouts of differential pairs 302, 304, and 306. In an example, width 376 may be one hundred and thirty mils. In this situation, the average width of the layouts of differential pairs 302, 304, and 306 may be forty-three mils. This average width of the layouts may improve routing density in PCB 300 as compared to PCB 100 described above with respect to FIGS. 1 and 2. The average width of the layouts may improve routing density in PCB 300 as compared to previous PCBs with multiple differential pairs that only have a layout similar to the layout of differential pair 302. One of ordinary skill in the art would recognize that widths 370, 372, 374, and 376 may be any suitable amounts without varying from the scope of this disclosure. In an example, widths 370, 372, and 374 of corresponding differential pairs 302, 304 and 306 enable a reduction of overall space and microstrip breakout trace lengths in PCB 300, which in turn may improve signal integrity for different pairs 302, 304 and 306 of PCB 300.

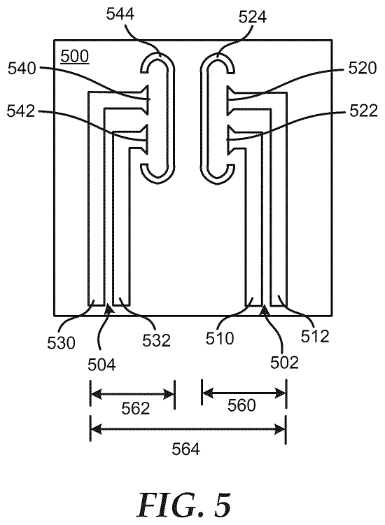

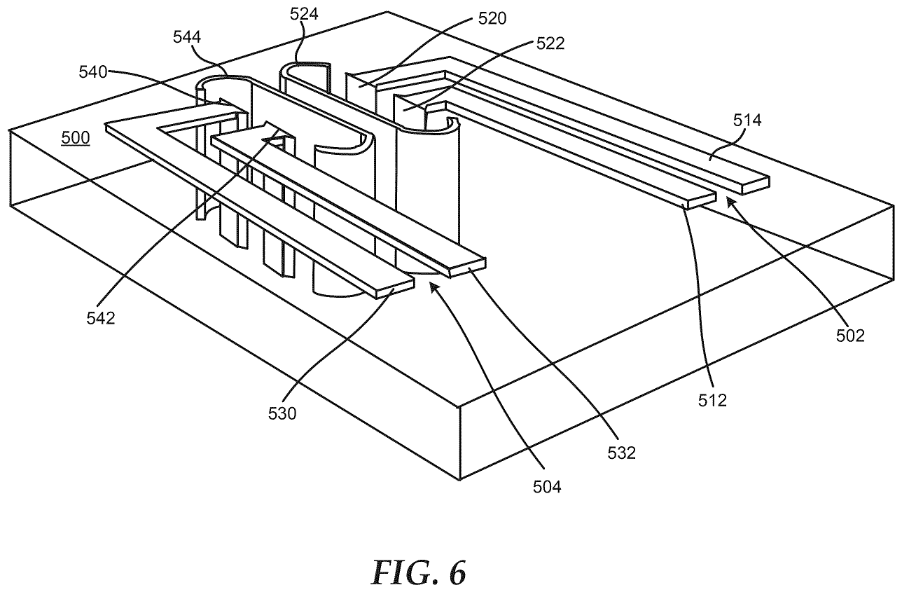

FIGS. 5 and 6 illustrate a portion of a PCB 500 of an information handling system, such as information handling system 800 of FIG. 8, according to at least one embodiment of the present disclosure. PCB 500 includes differential pairs 502 and 504. Different pair 502 is formed from signal traces 510 and 512. PCB 500 also includes vias 520 and 522, and a shield 524. Differential pair 504 is formed from signal traces 530 and 532. PCB 500 also includes vias 540 and 542 and a shield 544. While vias 520, 522, 540, and 542, and shields 524 and 544 are illustrated in FIG. 4 as extending from one surface of PCB 500 to the opposite surface of the PCB, these vias may extend in suitable distance within the PCB without varying from the scope of this disclosure. PCB 500 may include additional components without varying from the scope of this disclosure.

In certain examples, vias 520 and 522 may be orthogonal vias, such that the routing to and from the vias is at right angles. Vias 520 and 522 and shield 524 may be referred to as a VeCS slot. In an example, vias 520 and 522 and shield 524 may be plated with any suitable conductive material including, but not limited to, copper, silver, gold, zinc, and nickel. The details of forming VeCS vias in a PCB are known in the art and will not be further described herein, except as needed to illustrate the current embodiments.

After via 520 has been plated, signal trace 510 of differential pair 502 is routed on PCB 500, such that signal trace 510 is physically and electrically connected to via 520. In this situation, via 520 may connect signal trace 510 to one or more signal layers within PCB 500. In an example, after via 522 has been plated, signal trace 512 of differential pair 502 is routed on PCB 500, such that signal trace 512 is physically and electrically connected to via 522. In this example, via 522 may connect signal trace 512 to one or more signal layers within PCB 500.

In an example, vias 540 and 542 may be orthogonal vias, such that the routing to and from the vias is at right angles. Vias 540 and 542 and shield 544 may be referred to as a VeCS slot. In an example, vias 540 and 542 and shield 544 may be plated with any suitable conductive material including, but not limited to, copper, silver, gold, zinc, and nickel. The details of forming VeCS vias in a PCB are known in the art and will not be further described herein, except as needed to illustrate the current embodiments.

After via 540 has been plated, signal trace 530 of differential pair 504 is routed on PCB 500, such that signal trace 530 is physically and electrically connected to via 540. In this situation, via 540 may connect signal trace 530 to one or more signal layers within PCB 500. In an example, after via 542 has been plated, signal trace 532 of differential pair 504 is routed on PCB 500, such that signal trace 532 is physically and electrically connected to via 542. In this example, via 542 may connect signal trace 532 to one or more signal layers within PCB 500.

In an example, the orthogonal via pattern of vias 520 and 522 and the orthogonal via pattern of vias 540 and 542 may reduce crosstalk between different pairs 502 and 504 as compared to adjacent different pairs without an orthogonal via pattern. For example, crosstalk from vias 540 and 542 may be symmetrical with respect to vias 520 and 522, which in turn may create a low common mode noise on vias 520 and 522 from vias 540 and 542. For example, the noise from vias 540 and 542 may have equal amplitude but opposite polarity such that the common mode noise is rejected or cancelled on vias 520 and 522. In certain examples, traces 510 and 512 and vias 520 and 522 may have slight asymmetries due to manufacturing tolerances, skews, or the like. Similarly, traces 530 and 532 and vias 540 and 542 may have slight asymmetries due to manufacturing tolerances, skews, or the like. Based on these asymmetries, the noise cancellation may not be perfect between differential pairs 502 and 504. In an example, VeCS shields 524 and 544 located between vias 520 and 522 of differential pair 502 and corresponding vias 540 and 542 of differential pair 504 may block any common mode noise that is not cancelled based on the asymmetries. As described above, the orthogonal via pattern of vias 520 and 522 and the orthogonal via pattern of vias 540 and 542 may reduce cross talk between differential pairs 502 and 504 and improve common mode noise rejection between the differential pairs.

As illustrated in FIG. 5, different pair layouts in PCB 500 may have different widths. For example, the layout of differential pair 502 includes traces 510 and 512, vias 520 and 522, and shield 524 may have a width 560. Width 560 may be approximately thirty-two or thirty-four mils. The layout of differential pair 504 includes traces 530 and 532, vias 540 and 542, and shield 544 may have a width 562. Width 562 may be approximately thirty-two or thirty-four mils. In certain examples, width 560 of the layout of differential pair 502 and width 562 of the layout of differential pair 504 may combine to form an overall width 564 of layouts of differential pairs 502 and 504. In an example, width 564 may be sixty-four or sixty-eight mils. In this situation, the average width of the layouts of differential pairs 502 and 504 may be thirty-two or thirty-four mils. This average width of the layouts may improve routing density in PCB 500 as compared both PCB 100 described above with respect to FIGS. 1 and 2 and PCB 300 described above with respect to FIGS. 3 and 4. The average width of the layouts may improve routing density in PCB 500 as compared to previous PCBs with multiple differential pairs that only have a layout similar to the layout of differential pair 102 of FIGS. 1 and 2. One of ordinary skill in the art would recognize that widths 560, 562, and 564 may be any suitable amounts without varying from the scope of this disclosure. In an example, widths 560 and 562 of corresponding differential pairs 502 and 504 enable a reduction of overall space and microstrip breakout trace lengths in PCB 500, which in turn may improve signal integrity for different pairs 502 and 504 of PCB 500.

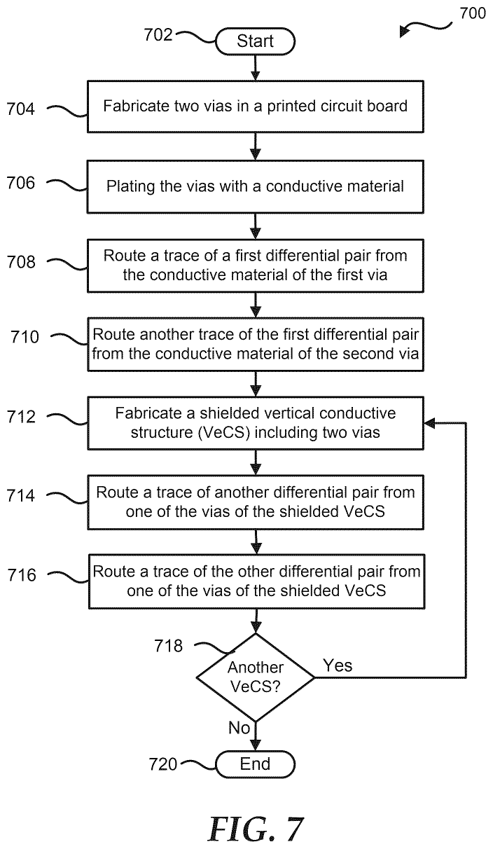

FIG. 7 is a flow diagram of method 700 for creating orthogonal vias within a printed circuit board according to at least one embodiment of the present disclosure, starting a block 702. It will be readily appreciated that not every method step set forth in this flow diagram is always necessary, and that certain steps of the methods may be combined, performed simultaneously, in a different order, or perhaps omitted, without varying from the scope of the disclosure.

At block 704, two vias are fabricated in a PCB. In an example, the vias may be any suitable type of via including, but not limited to, a through hole vias, a micro vias, and a skip vias. At block 706, the vias are plated with a conductive material. In an example, the conductive material may be copper. The details of PCB manufacture, and particularly the forming of vias and traces on a PCB are known in the art and will not be further described herein, except as needed to illustrate the current embodiments.

At block 708, a trace of a first differential pair is routed from the conductive material on one via. In an example, the electrical communication from the first trace to the conductive material of one via may provide a first signal path for a differential signal transmitted on the first differential pair. At block 710, another trace of the first differential pair is routed from the conductive material on the other via. The electrical communication from the second trace to the conductive material of the other via may provide a second signal path for the differential signal transmitted on the first differential pair.

At block 812, a VeCS slot is fabricated. In an example, VeCS slot may include two vias having an orthogonal via pattern and a shield. The vias and shield may be any suitable depth including, but not limited to, through hole, micro, and skip. During the fabrication of the VeCS slot, the vias and shield are plated with a conductive material. In an example, the conductive material may be copper. The details of PCB manufacture, and particularly the forming of a VeCS slot in a PCB are known in the art and will not be further described herein, except as needed to illustrate the current embodiments.

At block 708, a trace of a second differential pair is routed from the conductive material on one via of the VeCS slot. At block 710, another trace of the second differential pair is routed from the conductive material on the other vi of the VeCS slot. In an example, the electrical communication from the first trace to the conductive material of one via may provide a first signal path for a differential signal transmitted on the second differential pair. The electrical communication from the second trace to the conductive material of the other via may provide a second signal path for the differential signal transmitted on the second differential pair.

At block 718, a determination is made whether another VeCS slot is to be fabricated. If another VeCS is to be fabricated in the PCB, the continues as described above at block 712. If another VeCS is not to be fabricated in the PCB, the flow ends at block 720.

FIG. 8 illustrates a generalized embodiment of an information handling system 800. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 800 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 800 can include processing resources for executing machine-executable code, such as a central processing unit (CPU), a programmable logic array (PLA), an embedded device such as a System-on-a-Chip (SoC), or other control logic hardware. Information handling system 800 can also include one or more computer-readable medium for storing machine-executable code, such as software or data. Additional components of information handling system 800 can include one or more storage devices that can store machine-executable code, one or more communications ports for communicating with external devices, and various input and output (I/O) devices, such as a keyboard, a mouse, and a video display. Information handling system 800 can also include one or more buses operable to transmit information between the various hardware components.

Information handling system 800 can include devices or modules that embody one or more of the devices or modules described below, and operates to perform one or more of the methods described below. Information handling system 800 includes a processors 802 and 804, an input/output (I/O) interface 810, memories 820 and 825, a graphics interface 830, a basic input and output system/universal extensible firmware interface (BIOS/UEFI) module 840, a disk controller 850, a hard disk drive (HDD) 854, an optical disk drive (ODD) 856, a disk emulator 860 connected to an external solid state drive (SSD) 862, an I/O bridge 870, one or more add-on resources 874, a trusted platform module (TPM) 876, a network interface 880, a management device 890, and a power supply 895. Processors 802 and 804, I/O interface 810, memory 820, graphics interface 830, BIOS/UEFI module 840, disk controller 850, HDD 854, ODD 856, disk emulator 860, SSD 862, I/O bridge 870, add-on resources 874, TPM 876, and network interface 880 operate together to provide a host environment of information handling system 800 that operates to provide the data processing functionality of the information handling system. The host environment operates to execute machine-executable code, including platform BIOS/UEFI code, device firmware, operating system code, applications, programs, and the like, to perform the data processing tasks associated with information handling system 800.

In the host environment, processor 802 is connected to I/O interface 810 via processor interface 806, and processor 804 is connected to the I/O interface via processor interface 808. Memory 820 is connected to processor 802 via a memory interface 822. Memory 825 is connected to processor 804 via a memory interface 827. Graphics interface 830 is connected to I/O interface 810 via a graphics interface 832, and provides a video display output 836 to a video display 834. In a particular embodiment, information handling system 800 includes separate memories that are dedicated to each of processors 802 and 804 via separate memory interfaces. An example of memories 820 and 830 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 840, disk controller 850, and I/O bridge 870 are connected to I/O interface 810 via an I/O channel 812. An example of I/O channel 812 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 810 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 840 includes BIOS/UEFI code operable to detect resources within information handling system 800, to provide drivers for the resources, initialize the resources, and access the resources. BIOS/UEFI module 840 includes code that operates to detect resources within information handling system 800, to provide drivers for the resources, to initialize the resources, and to access the resources.

Disk controller 850 includes a disk interface 852 that connects the disk controller to HDD 854, to ODD 856, and to disk emulator 860. An example of disk interface 852 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 860 permits SSD 864 to be connected to information handling system 800 via an external interface 862. An example of external interface 862 includes a USB interface, an IEEE 4394 (Firewire) interface, a proprietary interface, or a combination thereof. Alternatively, solid-state drive 864 can be disposed within information handling system 800.

I/O bridge 870 includes a peripheral interface 872 that connects the I/O bridge to add-on resource 874, to TPM 876, and to network interface 880. Peripheral interface 872 can be the same type of interface as I/O channel 812, or can be a different type of interface. As such, I/O bridge 870 extends the capacity of I/O channel 812 when peripheral interface 872 and the I/O channel are of the same type, and the I/O bridge translates information from a format suitable to the I/O channel to a format suitable to the peripheral channel 872 when they are of a different type. Add-on resource 874 can include a data storage system, an additional graphics interface, a network interface card (NIC), a sound/video processing card, another add-on resource, or a combination thereof. Add-on resource 874 can be on a main circuit board, on separate circuit board or add-in card disposed within information handling system 800, a device that is external to the information handling system, or a combination thereof.

Network interface 880 represents a NIC disposed within information handling system 800, on a main circuit board of the information handling system, integrated onto another component such as I/O interface 810, in another suitable location, or a combination thereof. Network interface device 880 includes network channels 882 and 884 that provide interfaces to devices that are external to information handling system 800. In a particular embodiment, network channels 882 and 884 are of a different type than peripheral channel 872 and network interface 880 translates information from a format suitable to the peripheral channel to a format suitable to external devices. An example of network channels 882 and 884 includes InfiniBand channels, Fibre Channel channels, Gigabit Ethernet channels, proprietary channel architectures, or a combination thereof. Network channels 882 and 884 can be connected to external network resources (not illustrated). The network resource can include another information handling system, a data storage system, another network, a grid management system, another suitable resource, or a combination thereof.

Management device 890 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 800. In particular, management device 890 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 800, such as system cooling fans and power supplies. Management device 890 can include a network connection to an external management system, and the management device can communicate with the management system to report status information for information handling system 800, to receive BIOS/UEFI or system firmware updates, or to perform other task for managing and controlling the operation of information handling system 800. Management device 890 can operate off of a separate power plane from the components of the host environment so that the management device receives power to manage information handling system 800 when the information handling system is otherwise shut down. An example of management device 890 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 890 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board of an information handling system, the printed circuit board comprising:
a first differential pair fabricated on the printed circuit board, the first differential pair includes:
a first via connected to a first signal trace on the printed circuit board; and
a second via connected to a second trace on the printed circuit board; and
a second differential pair fabricated on the printed circuit board, the second differential pair includes:
a third via connected to a third signal trace on the printed circuit board;
a fourth via connected to a fourth trace on the printed circuit board, wherein the third and fourth vias have an orthogonal via pattern; and
a shield located between the first via and the third and fourth vias.

1. The printed circuit board of claim 1, wherein the third and fourth vias and the shield form a shielded vertical conductive structure.

2. The printed circuit board of claim 1, wherein a crosstalk from the third and fourth vias is symmetrical with respect to the first via.

3. The printed circuit board of claim 1, further comprises:
a third differential pair fabricated on the printed circuit board, the third differential pair includes:
a fifth via connected to a fifth signal trace on the printed circuit board;
a sixth via connected to a sixth trace on the printed circuit board, wherein the fifth and sixth vias have an orthogonal via pattern; and
a second shield located between the second via and the fifth and sixth vias.

4. The printed circuit board of claim 4, wherein the fifth and sixth vias and the second shield form a shielded vertical conductive structure.

5. The printed circuit board of claim 4, wherein the second shield provides common noise rejection between the third differential pair and the first differential pair.

6. The printed circuit board of claim 4, wherein a crosstalk from the fifth and sixth vias is symmetrical with respect to the second via.

7. The printed circuit board of claim 4, wherein a first layout of the first differential pair is wider than a second layout of the second differential pair.

8. The printed circuit board of claim 8, wherein a third layout of the third differential pair has a same width as the second layout of the second differential pair.

9. The printed circuit board of claim 1, wherein the shield provides common noise rejection between the second differential pair and the first differential pair.

10. An information handling system comprising:
a printed circuit board including:
a first differential pair fabricated on the printed circuit board, the first differential pair includes:
a first via connected to a first signal trace on the printed circuit board; and
a second via connected to a second trace on the printed circuit board;
a first shielded vertical conductive slot, the first shielded vertical conductive slot includes:
a third via connected to a third signal trace of a second differential pair on the printed circuit board;
a fourth via connected to a fourth trace of the second differential pair on the printed circuit board, wherein the third and fourth vias have an orthogonal via pattern; and
a first shield located between the first via and the third and fourth vias; and
a second shielded vertical conductive slot, the second shielded vertical conductive slot includes:
a fifth via connected to a fifth signal trace of a third differential pair on the printed circuit board;
a sixth via connected to a sixth trace of the third differential pair on the printed circuit board, wherein the fifth and sixth vias have an orthogonal via pattern; and
a second shield located between the second via and the fifth and sixth vias.

11. The information handling system of claim 11, wherein a crosstalk from the third and fourth vias is symmetrical with respect to the first via.

12. The information handling system of claim 11, wherein a first layout of the first differential pair is wider than a second layout of the second differential pair.

13. The information handling system of claim 13, wherein a third layout of the third differential pair has a same width as the second layout of the second differential pair.

14. The information handling system of claim 11, wherein a crosstalk from the fifth and sixth vias is symmetrical with respect to the second via.

15. The information handling system of claim 11, wherein the first shield provides common noise rejection between the second differential pair and the first differential pair.

16. The information handling system of claim 11, wherein the second shield provides common noise rejection between the third differential pair and the first differential pair.

17. A method comprising:
fabricating first and second vias in a printed circuit board of an information handling system;
plating the first via with a first conductive material;
plating the second via with a second conductive material;
routing a first trace of a first differential pair to the first conductive material of the first via;
routing a second trace of the first differential pair to the second conductive material of the second via;
fabricating a shielded vertical conductive structure in the printed circuit board of the information handling system, wherein the shielded vertical conductive structure includes: third and fourth vias and a shield;
plating the third via with a third conductive material;
plating the fourth via with a fourth conductive material;
plating the shield with a fifth conductive material;
routing a third trace of a second differential pair to the third conductive material of the third via; and
routing a second trace of the second differential pair to the fourth conductive material of the fourth via.

18. The method of claim 18, wherein the third and fourth vias have an orthogonal via pattern.

19. The method of claim 18, wherein the shield is located between the first via and the third and fourth vias.
